(19) United States
(12) Patent Application Publication
(10) Pub. No.: US 2026/0066910 A1
(43) Pub. Date: Mar. 5, 2026

(54) DIGITAL PREDICT AND LOAD OFFSET LOOP FOR CHOPPED SENSOR ADC

(71) Applicant: Infineon Technologies AG, Neubiberg (DE)

(72) Inventors: Dan Ioan Dumitru STOICA, Bucharest (RO); Radu MIHAESCU, Bucharest (RO); Ioan-Alexandru NICA, Suceava (RO); Oana-Claudia MANCIOIU, Bucharest (RO); Edwin Mario MOTZ, Wernberg (AT)

(21) Appl. No.: 19/310,490

(22) Filed: Aug. 26, 2025

(30) Foreign Application Priority Data
Sep. 4, 2024 (DE) 102024125315.0

(51) Int. Cl. H03M 1/06

(52) U.S. Cl. CPC H03M 1/0607

(57) ABSTRACT

An analog-to-digital converter (ADC) circuit includes a modulation circuit configured to modulate an input signal at a modulation frequency to generate a modulated signal; a combination circuit configured to combine the modulated signal with a feedback signal to generate a combined signal; a conversion circuit configured to convert, at a sampling frequency, the combined signal into a digital signal; a tracking register configured to store and update the digital signal; a prediction circuit configured to estimate a future value of the digital signal based on historical data from the digital signal, and load the estimated value into the tracking register at a modulation transition moment; a feedback circuit configured to convert a digital output signal of the tracking register into the feedback signal provided to the combination circuit; and a demodulation circuit configured to demodulate the digital signal at the modulation frequency to generate a digital demodulated output signal.

### CROSS REFERENCE TO RELATED APPLICATION

This application claims priority to Germany Patent Application No. 102024125315.0 filed on Sep. 4, 2024, the content of which is incorporated by reference herein in its entirety.

### TECHNICAL FIELD

The present disclosure relates to analog-to-digital converters, and more particularly to a digital offset ripple loop for chopped sensor analog-to-digital converters.

### BACKGROUND

Analog-to-digital converters (ADCs) are widely used in electronic systems to convert continuous analog signals into discrete digital representations. In many sensing applications, such as magnetic field sensing using Hall effect sensors, the analog signals of interest may be corrupted by offset and low-frequency noise. These undesired signal components can significantly degrade accuracy and resolution of the ADC output.

Chopping techniques have been employed to address offset and low-frequency noise issues in analog circuits. By modulating the input signal to a higher frequency before amplification and demodulating it after amplification, chopping can effectively separate the signal of interest from offset and low-frequency noise. However, implementing chopping in ADC systems may introduce additional challenges, such as residual offset due to charge injection and clock feedthrough in the chopping switches.

To further improve the performance of chopped ADC systems, various offset cancellation techniques have been developed. These techniques often involve complex analog circuitry or digital post-processing, which can increase power consumption, chip area, and system complexity. Additionally, many existing offset cancellation methods struggle to adapt quickly to changing offset conditions, potentially leading to temporary inaccuracies during transient periods.

In applications where the ADC is used intermittently or in a duty-cycled manner to reduce power consumption, a settling time required for the offset cancellation circuitry can become a significant limitation. This settling time may reduce the effective measurement time available within each active period, potentially compromising the signal-to-noise ratio of the converted signal.

Furthermore, the interaction between chopping, offset cancellation, and the ADC conversion process itself can lead to complex system dynamics. These interactions may result in residual ripple or spurs in the output spectrum, which can be challenging to eliminate without impacting the desired signal bandwidth or increasing system complexity.

As sensing systems continue to demand higher accuracy, lower power consumption, and faster response times, there is an ongoing need for improved ADC architectures that can effectively address offset and noise issues while maintaining simplicity and efficiency.

### SUMMARY

This need is addressed by circuits and methods in accordance with the appended claims.

According to a first aspect of the present disclosure, an ADC circuit for processing an input signal is proposed. The ADC circuit includes a modulation circuit configured to modulate the input signal at a modulation frequency to generate a modulated signal. The ADC circuit further includes a combination circuit configured to receive the modulated signal and combine it with a feedback signal to generate a combined signal. The ADC circuit also includes a conversion circuit configured to convert, at a sampling frequency, the combined signal into a digital signal. Additionally, the ADC circuit includes a tracking register configured to store and update the digital signal. The ADC circuit further includes a prediction circuit configured to estimate a future value of the digital signal based on historical data from the digital signal, and load the estimated value into the tracking register at a modulation transition moment. The ADC circuit also includes a feedback circuit configured to convert a digital output signal of the tracking register into the feedback signal provided to the combination circuit. Yet further, the ADC circuit includes a demodulation circuit configured to demodulate the digital signal at the modulation frequency to generate a digital demodulated output signal.

The proposed ADC circuit implements a digital offset ripple loop that predicts and loads estimated signal and/or offset values at modulation transition moments. This approach may allow for skipping a Successive Approximation Register (SAR) part of the conversion circuit when changing from one modulation phase to another. As a result, low 1/f noise is possible while reducing overall white noise due to increased averaging time. This configuration may be particularly advantageous for applications requiring high precision and low noise, such as in 3-dimensional (3D) sensors and consumer sensors where current consumption and noise are critical factors.

According to some implementations, the modulation circuit of the ADC circuit may include an analog chopper circuit configured to modulate the input signal at a chopping frequency to generate an analog chopped signal as the modulated signal. This allows for effective reduction of low-frequency noise and offset in the input signal, but also the reduction of the ADC input offset, improving the overall signal-to-noise ratio of the ADC.

According to some implementations, the combination circuit of the ADC circuit may be configured to determine a difference between the modulated (chopped) signal and the feedback signal. The minimization of this difference is the basis of SAR and ΣΔ analog to digital conversion.

According to some implementations, the conversion circuit of the ADC circuit may be configured to operate as an SAR ADC during a first operational mode and as a Sigma-Delta (ZA) ADC during a second operational mode. Thus, the conversion circuit of the ADC may be configured to operate in two distinct modes, each suited to different operational requirements. In the first mode, the circuit functions as a SAR ADC, which is known for its speed and efficiency in quickly converting an analog signal into a digital value through a binary search process. This mode is particularly useful for applications that require rapid conversions with moderate resolution. In the second mode, the circuit switches to operate as a ΣΔ ADC, which is characterized by its ability to provide high-resolution conversion and excellent noise shaping by oversampling the input signal and applying noise reduction techniques. This mode is ideal for scenarios where precision and low noise are critical. The ability to switch between SAR and ΣΔ modes allows for flexibility in balancing conversion speed and resolution, adapting to different signal conditions and application requirements.

According to some implementations, the first operational mode may be an initial operational mode after initial startup of the ADC circuit and the second operational mode may be a subsequent operational mode following the initial operational mode. The first operational mode of the ADC circuit may be used immediately after the circuit is powered on or initialized, serving as the initial operational mode. During this phase, the ADC operates in a mode that is likely optimized for quickly stabilizing the circuit and performing necessary calibrations, which may involve the use of a SAR ADC. Once the ADC has completed its initial startup procedures and the system has stabilized, the circuit transitions to the second operational mode. In this subsequent mode, the ADC might switch to ΣΔ ADC, which offers higher resolution and better noise performance, allowing for more accurate signal processing during normal operation. This configuration allows for rapid initial conversion using SAR, followed by high-resolution conversion using Sigma-Delta, optimizing both startup time and steady-state performance.

According to some implementations, the conversion circuit of the ADC circuit may include a signal processing circuit configured to process the combined signal and output a processed signal, a comparison circuit configured to compare the processed signal to a reference signal at the sampling frequency and generate a digital M-bit comparison output signal, and a conversion circuit configured to convert the digital M-bit comparison output signal into a digital N-bit signal. In the context of an ADC that can operate as both a SAR ADC and a ΣΔ ADC, the conversion circuit may include several key components that work together to digitize an analog input signal. First, the signal processing circuit processes the combined signal, which may include an amplified or integrated version of the input signal, depending on the specific configuration of the ADC. If the signal processing circuit is configured as an amplifier, it may boost the signal strength, making it more suitable for comparison. If configured as an integrator, it may sum the signal over time, which is particularly useful in noise reduction and in ΣΔ ADCs where integration is a crucial part of the modulation process. Once the signal has been processed, it is fed into the comparison circuit. The comparison circuit compares the processed signal against a reference signal at a defined sampling frequency. In a SAR ADC mode, the comparison circuit performs a series of comparisons to iteratively narrow down the range of the input signal, generating a digital output bit by bit, until it forms an M-bit digital comparison output signal that represents the signal with moderate resolution. After the comparison is complete, the conversion circuit further processes this M-bit digital comparison output signal to produce a higher resolution N-bit digital signal. When operating in ΣΔ ADC mode, the conversion circuit applies oversampling and noise shaping techniques to enhance the resolution and accuracy of the final digital output. This mode involves converting the M-bit comparison signal, which already reflects the basic characteristics of the input, into a more precise N-bit digital signal that minimizes noise and improves fidelity. The flexibility of the signal processing circuit to function as either an amplifier or integrator allows the ADC to adapt to different operational needs, making it versatile in both SAR and ΣΔ configurations. This structure allows for flexible signal processing and comparison, enabling efficient analog-to-digital conversion.

According to some implementations, the comparison circuit of the ADC circuit may include a comparator configured to generate, at each sampling moment, a 1-bit output signal based on the processed signal and the reference signal. The comparator may be configured to generate a 1-bit output signal at each sampling moment by comparing the processed signal with a reference signal. In the SAR ADC mode, the 1-bit output from the comparator is used in a successive approximation process. At each step, the comparator determines whether the input signal is above or below a midpoint value provided by a digital-to-analog converter (DAC). Based on the comparator's output, the SAR logic adjusts its approximation until the digital representation of the signal is accurately determined, with each step contributing to the formation of the final digital output. In the context of a ΣΔ ADC, the comparator may still generate a 1-bit output at each sampling moment, but the role of this output is slightly different. In ΣΔ modulation, the comparator's 1-bit output is part of a feedback loop where it continually compares the current state of the processed signal against a reference. This comparison is used to adjust the feedback within the ΣΔ modulator, shaping the noise and improving the signal's resolution over time. The continuous stream of 1-bit outputs from the comparator may then be averaged and processed to produce a high-resolution digital output.

According to some implementations, the tracking register of the ADC circuit may include an input configured to receive the estimated value and update the tracking register's contents with the received estimated value at the modulation transition moment. A tracking register is a component in an ADC circuit that stores digital values and updates them as the system processes signals. In the context of the ADC, the tracking register may ensure that the digital representation of the signal accurately follows or “tracks” the variations in the analog input signal over time. The tracking register in the ADC circuit is equipped with an input specifically configured to receive an estimated value, which is calculated by the system based on previous data or predicted signal behavior. At each modulation transition moment—when the ADC switches phases or changes how it modulates the input signal—the tracking register updates its contents with this estimated value. This update is important because modulation transitions can introduce variations or disturbances in the signal that need to be accounted for to maintain accuracy. By updating the tracking register with the estimated value at these critical moments, the ADC ensures that its internal digital representation of the signal remains accurate, effectively compensating for any shifts or offsets that may occur during the transition. This helps the ADC maintain a stable and precise output, even as the modulation process introduces changes to the input signal.

According to some implementations, the prediction circuit of the ADC circuit may include a Kalman filter configured to estimate the future value to be loaded into the tracking register by continuously updating an offset prediction based on a model of the ADC circuit's dynamics and current and previous digital N-bit signal samples. The Kalman filter provides an optimal estimation method, improving the accuracy of the prediction and consequently enhancing the ADC's performance.

According to some implementations, the prediction circuit of the ADC circuit may include a moving average filter configured to estimate the future value to be loaded into the tracking register by averaging a predefined number of recent digital N-bit signal samples. This simple yet effective prediction method can provide good results with low computational complexity.

According to some implementations, the prediction circuit of the ADC circuit may include a machine learning model trained to predict the future value to be loaded into the tracking register based on historical data and patterns identified in the digital N-bit signal. This advanced prediction method can adapt to complex signal patterns, potentially improving the ADC's performance in challenging applications.

According to some implementations, the ADC circuit may further include a sensor configured to generate an analog sensor signal as the input signal. The sensor may be any device that detects and measures a physical phenomenon and converts it into an analog electrical signal. For example, a temperature sensor might produce an analog voltage proportional to the temperature it senses, while a pressure sensor might generate an analog current corresponding to the pressure level. In the context of magnetic field sensors, such as Hall effect sensors or magnetoresistive sensors, the sensor may detect changes in magnetic fields and produces a corresponding analog voltage or current. This analog sensor signal is then fed into the ADC circuit, where it undergoes conversion into a digital format that can be further processed, analyzed, or used in digital systems. By incorporating the sensor directly into the ADC circuit, the system can more effectively and accurately convert real-world analog signals into precise digital data, enabling a wide range of applications, from environmental monitoring to industrial automation and beyond.

According to some implementations, the sensor of the ADC circuit may include a spinning Hall sensor. A spinning Hall sensor operates by rapidly rotating or “spinning” Hall sensing elements within the sensor. This rotation helps to average out any offsets or errors that may arise due to imperfections in the sensor elements or external influences. The concept of spinning in the Hall sensor is related to the technique of chopping used in the ADC circuit. Both spinning and chopping are methods configured to reduce or eliminate offset errors and low-frequency noise, such as 1/f noise. In a spinning Hall sensor, the continuous rotation of the sensing elements acts similarly to chopping by modulating the signal and its associated offset errors. This modulation shifts the errors to higher frequencies, where they can be more easily filtered out by the ADC. Therefore, when the spinning Hall sensor is combined with an ADC circuit that uses chopping, the two techniques work together to enhance the accuracy and stability of the sensor's output, providing a more precise digital representation of the magnetic field being measured.

According to some implementations, the modulation frequency of the ADC circuit may be lower than the sampling frequency. The modulation frequency, or chopping frequency, of the ADC circuit refers to the rate at which the input signal is modulated to help reduce noise and offset errors. The sampling frequency, on the other hand, is the rate at which the ADC samples the input signal or its derivates to convert it from an analog to a digital form. When the modulation frequency is lower than the sampling frequency, it means that the input signal is being modulated at a slower rate than it is being sampled. This setup allows the ADC to take multiple samples of the signal during each cycle of modulation, providing a more detailed digital representation of the signal within each modulation phase. By having a higher sampling frequency, the ADC can more effectively capture the signal's dynamics and improve the accuracy of the conversion, while the lower modulation frequency still effectively shifts low-frequency noise and offsets to a higher frequency, where they can be more easily filtered out.

According to another aspect of the present disclosure, an ADC method for processing an input signal is proposed. The method includes modulating the input signal at a modulation frequency to generate a modulated signal, combining the modulated signal with a feedback signal to generate a combined signal, converting the combined signal into a digital signal at a sampling frequency, storing and updating the digital signal in a tracking register, estimating a future value of the digital signal based on historical data from the digital signal, and loading the estimated value into the tracking register at a modulation transition moment, converting a digital output signal of the tracking register into the feedback signal, and demodulating the digital signal at the modulation frequency to generate a digital demodulated output signal.

According to yet another aspect of the present disclosure, an ADC circuit for converting an analog input signal to a digital output signal is proposed. The ADC circuit includes a forward path including an analog chopper circuit configured to shift the analog input signal from an original frequency to a chopper frequency to generate a chopped analog signal, a conversion circuit configured to convert, at a sampling frequency, the chopped analog signal into a chopped digital signal, and a digital chopper circuit configured to shift the chopped digital signal from the chopper frequency to the original frequency. The ADC circuit further includes a feedback path including a digital-to-analog converter (DAC). Additionally, the ADC circuit includes a digital offset compensation circuit configured to predict an offset or signal value of the chopped digital signal based on previous sampling cycles, generate a digital compensation signal based on the predicted offset or signal value, and load the digital compensation signal into the feedback path at the start of a new chopping phase.

The ADC circuit implements a digital offset ripple loop with prediction and loading of compensation signals at the start of new chopping phases. This approach allows for efficient handling of offset and chopping effects, potentially improving the ADC's performance in terms of noise reduction and signal accuracy. The combination of analog and digital chopping techniques provides effective noise suppression across a wide frequency range.

According to some implementations, the conversion circuit of the ADC circuit may be configured to operate as SAR ADC at the beginning of a chopping phase and as ΣΔ ADC during a remainder of the chopping phase, wherein loading the digital compensation signal into the feedback path enables the conversion circuit to skip the SAR operation when changing from one chopping phase to another. This hybrid SAR-ΣΔ approach, combined with the predictive loading of compensation signals, allows for fast initial conversion and high-resolution subsequent conversion while minimizing the impact of chopping phase transitions. This can lead to improved overall ADC performance, particularly in terms of conversion speed, resolution, and noise reduction.

Implementations of the present disclosure may offer several advantages over conventional approaches. Firstly, the proposed design may improve noise performance of the ADC circuit by enabling continuous operation in ΣΔ mode, effectively eliminating the need for SAR conversions during chopping phase transitions. This may result in a notable reduction in overall noise, with simulations indicating up to a 1.4× improvement in signal-to-noise ratio (SNR) compared to traditional SAR-tracking ΣΔ (SAT) systems.

Additionally, the predictive nature of the digital offset ripple loop may allow for superior signal tracking, particularly for moderately fast-changing signals. By estimating future signal or offset values based on historical data, the system can rapidly adapt to changing input conditions, maintaining high accuracy even during transient periods. This feature is especially beneficial in applications with dynamic input signals, such as in magnetic field sensing or motion detection.

Furthermore, the digital implementation of the offset ripple loop may offer enhanced flexibility and scalability compared to analog alternatives. The ability to utilize various prediction algorithms, such as Kalman filters, moving averages, or even machine learning models, allows for customization based on specific application requirements. This adaptability enables optimized performance across a wide range of sensing scenarios, from high-precision industrial measurements to power-efficient consumer devices.

Implementations of the present disclosure also address the challenges associated with duty-cycled operation in pulsed output sensors. By minimizing the settling time required at the beginning of each active period, this technique maximizes the effective measurement time within each cycle. This optimization contributes to improved SNR and enables more efficient power management in battery-operated or energy-harvesting sensor systems.

Also, the digital nature of the offset ripple loop may facilitate easier integration with modern digital signal processing techniques and microcontroller-based systems. This compatibility may enhance the overall system flexibility and allows for future upgrades or modifications through firmware updates, providing a future-proof solution for evolving sensing applications.

### BRIEF DESCRIPTION OF THE DRAWINGS

Some examples of apparatuses and/or methods will be described in the following by way of example only, and with reference to the accompanying figures, in which

FIG. 1 shows a schematic block diagram of a sensor system comprising a chopped ADC circuit;

FIG. 2 shows a block diagram of an implementation of the proposed ADC circuit; and

FIG. 3 shows an example timeline of measurement channels and chopping phases and the transition between SAR and ΣΔ modes for the proposed ADC circuit.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

Sensors often introduce errors into an analog signal they output due to intrinsic characteristics of the sensors themselves. For example, an offset error may be included in an analog signal output by a Hall sensor. However, spinning current techniques may help to distinguish between the error and the sensor signal as will be described in more detail below. The spinning technique may transform the offset error component in the Hall sensor signal into a high frequency error (called offset ripple) while the sensor signal remains low frequency or DC.

ADCs may include amplifiers and/or integrators that may also introduce an offset error into the signals they process. The amplifier or integrator offset error may add to the offset error introduced by the Hall sensor. To compensate for the sensor's offset error and/or amplifier offset error, some ADCs include choppers. Choppers are circuits that modulate the sensor signal to a higher frequency, which shifts the sensor output signal to a higher frequency range (e.g., the chopping frequency fchop) while the offset error component remains in a lower frequency range, making the offset error component easier to distinguish from the signal component. For the purposes of this description, the modulated sensor signal at the chopping frequency output by chopper circuit will be referred to as being “chopped” or “at the chopping frequency” to be contrasted with sensor signals that have not been modulated or have been re-modulated to the original frequency of the sensor signal, which will be referred to as having “the original frequency.”

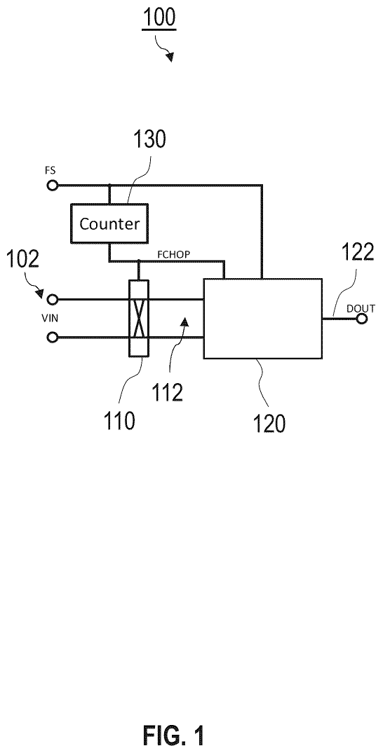

FIG. 1 illustrates a schematic block diagram of a sensor system that comprises a (chopped) ADC circuit 100 for converting an analog input signal VIN (e.g., a sensor signal) at an original frequency to a digital output signal DOUT.

The analog input signal VIN may be assumed to be band-limited, and the signal bandwidth may be assumed to be much lower than a sampling frequency fs of the ADC circuit 100. The analog input signal VIN may include a signal component and an offset error component that may be introduced by a sensor (not shown) measuring a physical quantity (e.g., a Hall sensor to measure a magnetic field). To account for the offset error component in the analog input signal VIN, the ADC circuit 100 comprises a chopper circuit 110 coupled between an input terminal 102 for the analog input signal VIN and an input terminal of an A/D conversion circuit 120. The chopper circuit 110 may be considered external to the A/D conversion circuit 120 and comprises a modulator circuit which is clocked at a chopping frequency fchop. A/D conversion circuit 120 may comprise an internal analog or digital demodulator circuit (not shown) which is also clocked at chopping frequency fchop. The chopping frequency fchop may be lower than the sampling frequency fs of the ADC circuit 100. A chopping clock signal at chopping frequency fchop may be derived from a sampling clock signal at sampling frequency fs using a timing circuit 130. Timing circuit 130 may be configured to perform a frequency division of the sampling frequency fs to obtain the chopping clock signal at chopping frequency fchop. For example, this may be done via a counter which triggers a state transition (from low to high, or from high to low) of the chopping clock signal after j sampling clock pulses. The chopper or modulator circuit 110 is configured to shift the analog input signal VIN from its original frequency (which may be DC) to the chopping frequency fchop to generate a chopped analog signal 112 at the input of A/D conversion circuit 120.

The general ADC circuit 100 described in FIG. 1 effectively utilizes a chopper circuit to modulate the analog input signal and shift its frequency to mitigate offset errors introduced by the sensor and/or ADC itself. Despite any analog or digital demodulation provided within A/D conversion circuit 120, the digital conversion process would not be able to follow the (signal and offset) transitions caused by the modulation in tracking mode and/or ΣΔ mode. Only SAR mode would be able to follow these transitions, but at the expense of reduced effective measurement time within each cycle. To address this issue and further reduce the remaining offset ripple, a more sophisticated ADC circuit is proposed, incorporating additional features such as tracking and prediction circuits. These enhancements aim to anticipate and correct for the offset ripple dynamically, thereby significantly improving the overall accuracy and stability of the digital output signal.

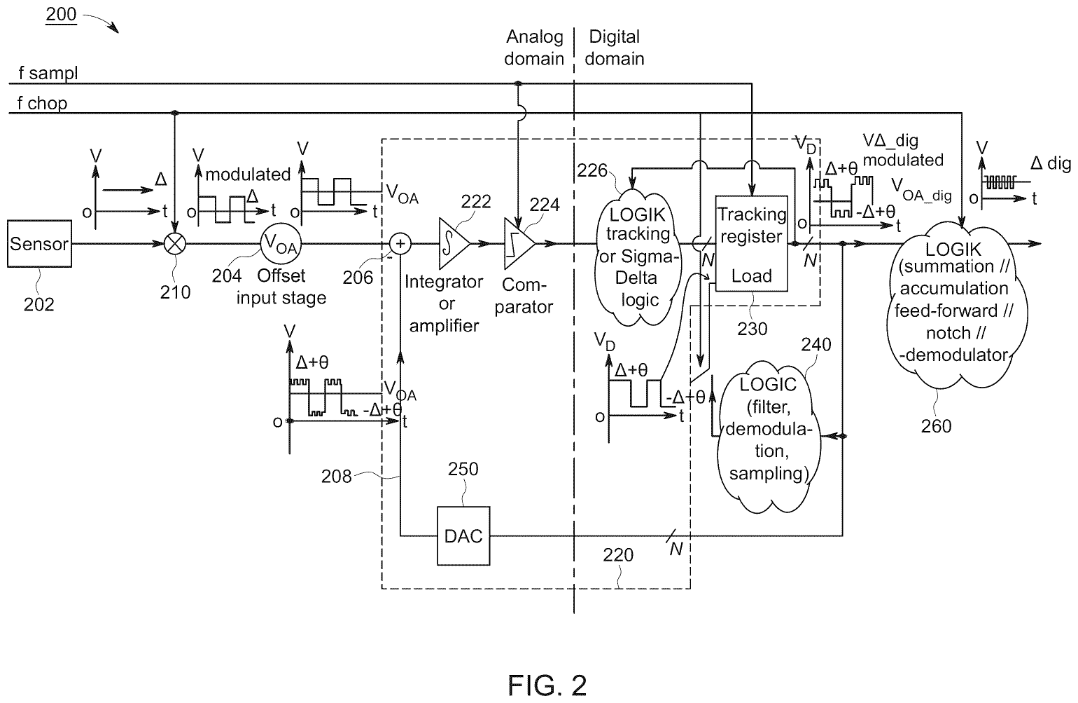

A block diagram of an implementation of the proposed ADC circuit 200 is shown in FIG. 2. The skilled person having benefit from the present disclosure will appreciate that also alternative implementations are conceivable.

FIG. 2 shows a sensor 202 measuring a physical quantity (e.g., a Hall sensor to measure a magnetic field). Sensor 202 provides an analog sensor signal. The analog sensor signal may comprise a sensor signal component as well as an offset signal component. The analog sensor signal serves as input signal to analog chopper circuit 210 which is clocked at chopping frequency fchop. Analog chopper circuit 210 is configured to modulate the analog sensor signal at the chopping frequency fchop to generate an analog chopped sensor signal. Analog chopper circuit 210 may include a set of analog switches or transistors that are used to periodically invert or modulate the analog sensor signal. These switches are controlled by a clock signal operating at the chopping frequency fchop. When the switches are in one state, the analog sensor signal from the sensor 202 may pass through normally. When the switches flip to the opposite state, the signal is inverted. This periodic switching effectively modulates the sensor signal by multiplying it with a square wave that oscillates at fchop.

The analog chopped sensor signal may be provided to an input stage 204, such as an amplifier stage, for example. Amplifiers, such as input stage 204, may have an inherent offset voltage, which is a small DC voltage that exists at the amplifier's output even when the input is zero. This offset voltage may be a result of mismatches in transistors or other components within the amplifier's internal circuitry. It may arise due to variations in manufacturing, differences in transistor threshold voltages, and other imperfections in the amplifier design. The offset introduced by the amplifier adds to any offset in the chopped sensor signal, potentially leading to a cumulative offset error. This cumulative offset can reduce the accuracy of a final digital signal output by the ADC, as it may cause the baseline of the signal to shift, leading to incorrect interpretation of the sensor data. Even though chopper circuit 210 initially helps to modulate the offset to higher frequencies, the input stage's 204 own offset can reintroduce a low-frequency offset component, which could manifest as offset ripple in the processed signal.

Downstream to input stage 204, ADC circuit 200 further comprises a conversion circuit 220 configured to convert, at sampling frequency fs, the combined signal from combination circuit 206 into a digital signal. Conversion circuit 220, located downstream of the input stage 204, is responsible for converting the combined analog signal into a digital signal at the sampling frequency fs. Conversion circuit 220 comprises a combination circuit 206 configured to receive the analog chopped sensor signal from input stage 204 and combine it with a feedback signal 208 to generate a combined signal. In the illustrated example, combination circuit 206 is configured to determine a difference between the analog chopped sensor signal from input stage 204 and the feedback signal 208. By determining the difference between the analog chopped sensor signal and the feedback signal, the combination circuit 206 may cancel out or at least reduce any remaining offset or noise that may have been introduced during various signal processing stages. The generation of feedback signal 208 will explained in more detail below.

One possible implementation of the conversion circuit 220 is as a traditional SAR ADC. In this setup, the SAR ADC may work by iteratively comparing the analog input signal against reference voltages, narrowing down the value of the signal in a step-by-step binary search process until a precise digital representation is obtained. Another implementation of the conversion circuit 220 could involve a ΣΔ ADC. In this case, the circuit may oversample the combined signal at a rate much higher than the Nyquist frequency and use noise shaping to push quantization noise to higher frequencies, which are then filtered out. This may result in a high-resolution digital signal that accurately reflects the input signal, especially in applications requiring low noise and high precision. Another implementation illustrated in FIG. 2 may incorporate Successive Approximation Tracking (SAT), which combines elements of both SAR and ΣΔ techniques. In SAT, the conversion circuit 220 initially uses a SAR approach to quickly approximate the analog input signal, providing a coarse digital output. Following this, a ΣΔ modulator may refine the digital signal by tracking the signal more closely over time, further reducing noise and improving resolution. As such, the conversion circuit 220 may be configured to operate as SAR ADC during a first operational mode and as a ΣΔ ADC during a second operational mode. This dual-mode operation may leverage the speed of SAR for initial approximation and the precision of ΣΔ for fine-tuning, making it particularly useful in applications where both speed and accuracy are essential.

As shown in the example of FIG. 2, the conversion circuit 220 may comprise a signal processing circuit 222 configured to process the (analog) combined signal from combination circuit 206 and output a processed signal. Downstream to signal processing circuit 222, conversion circuit 220 may comprise a comparison circuit 224 configured to compare the processed signal from signal processing circuit 222 to a reference signal at the sampling frequency fs and generate a digital M-bit comparison output signal. Downstream to comparison circuit 224, conversion circuit 220 may comprise a conversion circuit/logic 226 configured to convert the digital M-bit comparison output signal into a digital N-bit signal, where N may be larger than M.

Depending on the implementation of conversion circuit 220, signal processing circuit may comprise an integrator and/or an amplifier. For SAT, signal processing circuit 222 may be configured as amplifier during the first operational mode (SAR mode) and as integrator during the second operational mode (ΣΔ mode).

The conversion circuit 220 in ADC circuit 200 transforms the combined analog signal from the combination circuit 206 into a digital signal. This process may begin with the signal processing circuit 222, which may be used for preparing the (analog) combined signal for digitization. Depending on the configuration, the signal processing circuit 222 can function as an integrator, an amplifier, or both. When signal processing circuit 222 is configured as an amplifier, it boosts the strength of the signal, making it more suitable for comparison. On the other hand, when configured as an integrator, signal processing circuit 222 sums the signal over time, which is especially useful for ΣΔ ADCs where integration is key to accurate signal representation. Downstream of the signal processing circuit 222, the processed analog signal is fed into the comparison circuit 224. The comparison circuit 224 operates by comparing the processed signal to a reference signal at each sampling moment, determined by the sampling frequency fs. This comparison results in a digital output that, in one implementation, consists of an M-bit word. In particular, M may be 1. Following the comparison, the digital M-bit output is passed to another component within the conversion circuit 220, referred to as the conversion circuit or logic 226. This component further processes the M-bit signal, refining it into an N-bit digital signal. The N-bit signal represents a final, high-resolution digital output that reflects the original analog input.

In a system that employs SAT, the signal processing circuit 222 is dynamically configured to optimize the conversion process depending on the operational mode. During the first operational mode, also referred to as SAR mode, the signal processing circuit 222 functions as an amplifier. This mode allows the system to quickly approximate the signal by iteratively refining the output bit by bit through successive comparisons. Once this coarse approximation is complete, the system may transition to the second operational mode, also referred to as ΣΔ mode. In this mode, the signal processing circuit 222 switches to function as an integrator. This change allows the circuit to accumulate and refine the signal more precisely, leveraging the noise shaping benefits of ΣΔ modulation to achieve higher resolution in the final digital output. The dual functionality of the signal processing circuit, combined with the capabilities of the comparison and conversion circuits, ensures that ADC circuit 200 can adapt to different requirements for speed and precision, providing a versatile and accurate solution for analog-to-digital conversion.

Downstream to conversion circuit/logic 226, conversion circuit 220 comprises a tracking register 230 configured to store and update the digital signal from conversion circuit 220. Tracking register 230 is a digital component that may be used to store and continuously update a digital representation of the signal being processed. It may act as a memory element that holds the current value of the digital signal and updates it as new data becomes available from the conversion circuit 220. Tracking register 230 may keep track of changes in the signal over time, allowing the system to predict and correct for any variations, such as offset errors or noise, that might affect the accuracy of the final output. In operation, tracking register 230 may work by receiving the digital signal from the conversion circuit 220, which could be the result of a SAR ADC, a ΣΔ ADC, or a combination of both in the case of SAT. Each time the conversion circuit 220 produces a new digital value, tracking register 230 may update its contents with this value. This continuous updating ensures that tracking register 230 always contains the most current and accurate digital representation of the input signal.

The proposed ADC circuit 200 further includes a prediction circuit 240 which is configured to estimate a future value of the digital signal based on historical data from the digital signal, and load the estimated value into the tracking register 230 at a chopping transition moment. The prediction circuit 240 in the proposed ADC circuit 200 is configured to anticipate or estimate the future value of the digital signal based on present and historical data, ensuring that the ADC system remains accurate and responsive to changes in the signal. Prediction circuit 240 may help maintaining signal integrity, particularly during chopping transition moments when the analog input signal might undergo sudden shifts due to the modulation/chopping process. Examples of the prediction circuit 240 include several types of digital signal processing techniques. One example is a Kalman filter, which uses a mathematical model of ADC circuit 200 to predict future values by continuously updating its estimates based on past and current measurements. Another example is a moving average filter, which calculates the average of the most recent signal values to smooth out short-term fluctuations and provide a stable estimate for the next value. Another example could be a machine learning algorithm, such as a neural network, trained to recognize patterns in the signal data and predict future values based on these patterns. The prediction circuit 240 may estimate the future or next value of the digital signal by analyzing historical data from the digital signal stored in tracking register 230 or other memory components. By recognizing trends or patterns in the previous values, the prediction circuit 240 can forecast what the signal is likely to be at the next chopping transition. This predictive approach helps the ADC system adjust for any expected changes in the signal (at chopping transitions), thereby reducing the impact of noise or offset errors that might otherwise distort the output. The estimated value may be loaded into the tracking register 230 specifically at a chopping transition moment because this is a critical time when the signal might be most vulnerable to changes. During a chopping transition, the ADC circuit 200 switches the phase or modulation of the input signal, which can introduce transient effects or shifts in the signal's baseline. By loading the estimated value into the tracking register at this moment, the system ensures that the register holds the most accurate possible representation of the signal, compensating for any sudden changes caused by the chopping process.

The estimated value that is loaded into the tracking register at chopping transitions is indeed an estimate of the signal (and often the offset) expected during the upcoming chopping phase. When ADC circuit 200 transitions from one chopping phase to the next, the characteristics of the signal might change, particularly because the chopping process modulates the signal, effectively flipping its polarity. To prepare for these changes and to ensure that the tracking register 230 starts with the most accurate possible value, the system calculates an estimate of what the signal and offset will be in the next phase. Just before the new chopping phase begins, this calculated estimate is loaded into the tracking register 230. By doing this, the system may ensure that the tracking register 230 is initialized with a value that closely matches the expected signal at the start of the next chopping phase. The estimate takes into account the historical data from previous phases, as well as any known patterns or expected changes in the signal and offset. By anticipating what the signal will look like in the next chopping phase, the conversion circuit 220 can continue to track and process the signal accurately, without being thrown off by the phase transition.

The conversion circuit 220 also comprises a feedback circuit 250 configured to convert a digital output signal of the tracking register 230 into the feedback signal 208 provided to the combination circuit 206. As shown in FIG. 2, feedback circuit 250 may comprise a digital-to-analog converter (DAC) to convert the digital output signal of the tracking register 230 into the feedback signal 208. DAC 250 may be clocked at the sampling frequency fs. The feedback circuit 250 may continuously convert the digital output signal from the tracking register 230 back into an analog signal, e.g., the feedback signal 208. This (analog) feedback signal 208 is then provided to the combination circuit 206, where it is used to adjust the input to the conversion circuit 220 dynamically. Specifically, the feedback circuit 250 may include a DAC which is responsible for this conversion process. The DAC takes the digital signal stored in the tracking register 230—representing the latest, most accurate digital representation of the sensor signal—and transforms it into an analog signal that can be used to fine-tune the ongoing ADC process. The DAC is typically clocked at the sampling frequency fs, ensuring that the feedback signal is updated in sync with the ADC's sampling rate, thereby maintaining the accuracy and responsiveness of the system.

There may be alternative implementations for the feedback circuit 250 beyond the DAC approach. For instance, the feedback signal 208 could be generated using a digitally controlled variable resistor or a digitally controlled current source, which adjusts the analog signal based on the digital output without a full conversion back to analog form. Another alternative could involve using a pulse-width modulation (PWM) circuit, where the digital signal modulates the width of a series of pulses that are then averaged out to create the feedback signal. These alternative methods might be used in specific applications where power consumption, cost, or the need for ultra-fast response times are critical factors.

Yet further, ADC circuit 200 comprises a demodulation circuit/logic 260 configured to demodulate the digital signal at the chopping frequency fchop to generate a digital demodulated output signal. Demodulation circuit/logic 260 may also comprise one or more digital filters, such as notch filters, for example. Demodulation circuit or logic 260 is responsible for converting the modulated (chopped) digital signal back to its original frequency after the signal has been processed through the chopping process. Chopping is used to shift the signal to a higher frequency where noise and offsets can be more effectively managed. However, to obtain a usable final output, the signal needs to be demodulated back to its base frequency, which is the role of the demodulation circuit or logic 260. This circuit operates at the chopping frequency fchop, ensuring that the digital signal is accurately shifted back, removing the effects of modulation and restoring the signal to a form that represents the original sensor input. In addition to demodulation, the demodulation circuit or logic 260 may include digital filters, such as notch filters. These filters may be specifically configured to target and remove any residual noise or specific unwanted frequency components, like offset ripple, that remain after demodulation. Notch filters, for example, may be useful for eliminating narrow frequency bands where interference or noise is present, ensuring that the final digital output signal is clean and accurate. By incorporating such filters, the demodulation circuit 260 may not only restore the signal to its original frequency but also enhance its quality by reducing noise and offset ripple, leading to a more precise and reliable digital demodulated output signal.

ADC circuit 200 is configured to improve the accuracy and stability of signal conversion by addressing offset ripple and reducing low-frequency noise. ADC circuit 200 implements a digital offset ripple loop that predicts or estimates the offset (or signal) and loads the corresponding value at the start of each new spinning or chopping phase. This predictive capability may help maintain a consistent signal output by compensating for any expected changes in the offset, particularly during transitions between different operational phases. A key aspect of the proposed concept is its approach to phase transitions. The SAR part of the conversion process may be skipped when changing from one chopping phase to another. This strategy may be employed to minimize errors and disturbances that could arise during these transitions, which are moments when the signal might be particularly vulnerable to changes or noise. By focusing on high-frequency chopping, the system is able to retain these benefits while also making it possible to reduce low 1/f noise, a type of noise that typically affects the lowest frequencies and can degrade signal quality.

ADC circuit 200 may only employ the chopped Sigma-Delta (ΣΔ) mode after startup. During startup, the system may use different modes to quickly stabilize the signal, but once stabilized, it may rely exclusively on the chopped ΣΔ mode to maintain high accuracy and minimize noise.

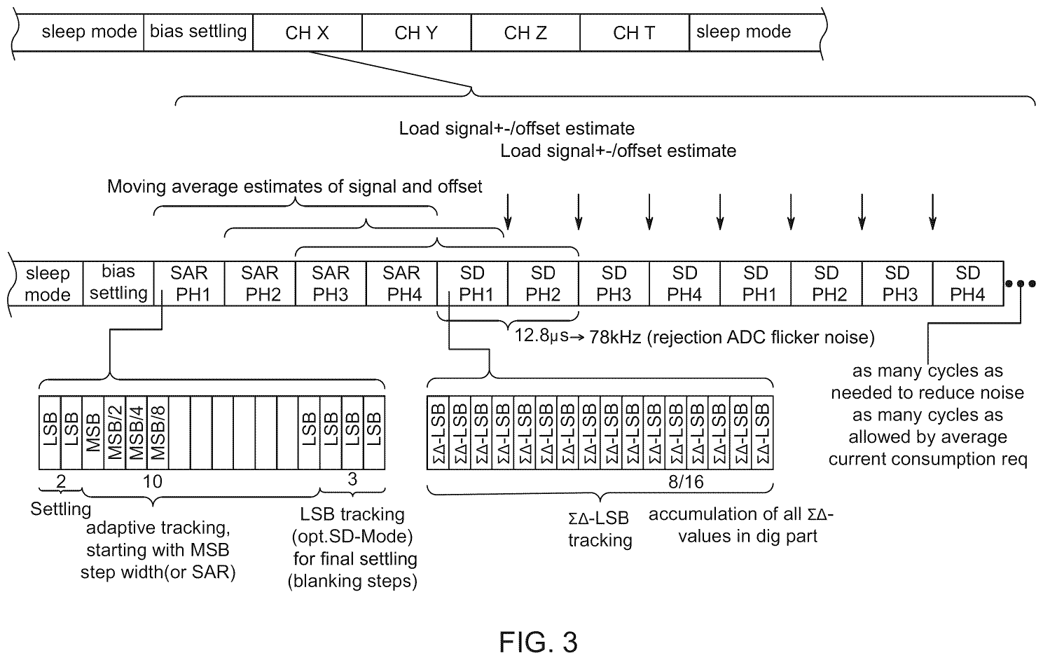

FIG. 3 depicts an example timeline of various measurement channels (CH X, CH Y, CH Z, CH T), chopping phases (PH1-PH4) within each measurement channel, and the transition between SAR and ΣΔ modes.

The channels CH X, CH Y, CH Z, and CH T may correspond to measuring X-, Y-, Z-components of a magnetic field as well as a temperature value, for example. FIG. 3 shows several operational periods, starting with a sleep mode, where the system is inactive to conserve power, followed by a bias settling period. This bias settling phase may allow the system to stabilize after waking up from sleep mode, ensuring that the sensor(s) and ADC are ready to accurately process signals. After bias settling and for each measurement channel, the system enters multiple initial SAR chopping phases (SAR PH1-SAR PH4), where the conversion circuit 220 operates in SAR ADC mode. During these initial chopping phases, the system performs successive approximation to quickly approximate the sensor signal. The SAR mode involves adaptive tracking, beginning with a large step width for the Most Significant Bit (MSB) and gradually narrowing down to the Least Significant Bit (LSB) for fine resolution. This approach allows for a fast initial approximation of the signal, which is then further refined.

Following the initial SAR chopping phases, the system transitions to subsequent ΣΔ chopping phases (SD PH1-SD PH4). Here, the conversion circuit 220 switches to and remains in ΣΔ ADC mode. During these ΣΔ chopping phases, the signal is tracked with high precision using ΣΔ modulation, which is known for its noise shaping capabilities and high resolution. The ΣΔ chopping phases are used to further refine the signal, reducing noise and offset errors that may have persisted after the initial SAR phases. FIG. 3 indicates that during these ΣΔ chopping phases, the system can perform multiple cycles to further reduce noise, depending on the requirements for average current consumption and noise reduction. The ΣΔ ADC may be particularly effective in rejecting flicker noise (low-frequency noise).

FIG. 3 also shows that moving average estimates of the (digital) signal and offset may be loaded into the tracking register 230 at chopping transition moments between adjacent ΣΔ chopping phases. As the system progresses from one ΣΔ chopping phase to the next, there are moments of transition where the signal processing could be vulnerable to sudden changes or noise, which might affect the accuracy of the output. To mitigate this, moving average estimates of the digital signal, which may have been calculated by prediction circuit 240 during the preceding chopping phase, are loaded into the tracking register 230 at these transition moments and fed back to combination circuit 206. By doing this, the system ensures that the tracking register 230 holds a stable and accurate estimate of the signal and offset as it enters the next chopping phase. Loading these averaged estimates into the tracking register 230 at the exact moment of transition between adjacent ΣΔ chopping phases helps the system to “lock in” a reliable value, preventing the introduction of errors that could arise from any abrupt changes or disturbances during the transition.

ADC circuit 200 may effectively handle quasi-constant signals and offsets while minimizing noise and instability, especially during chopping phase transitions. To address these challenges, two example approaches will be described. Each approach offers unique strategies for tracking the signal and offset, as well as for mitigating quantization noise and potential oscillations during critical transitions between chopping phases.

Assume two chopping phases, where the sensor signal and offset are nearly constant (quasi-constant), allowing ADC circuit 200 to predict and correct these values efficiently. The system operates in two chopping phases, where the sensor signal is modulated (chopped) between a positive and a negative chopping phase. During these chopping phases, the tracking register 230 may store a value that includes both the signal and the offset. One example implementation may focus on estimating the signal using a moving average from previous phases, which may then be used to correct the tracked value. This approach may involve calculating a mirrored tracking value that remains positive, helping to minimize quantization noise and maintain stability, particularly during phase transitions. In another implementation, the system instead may estimate the offset by taking a moving average of the offset from previous phases. The tracking value may be mirrored around a midpoint and adjusted using the offset estimate, resulting in an inverted sign compared to the first method. This approach may be more effective in handling rapid signal changes, making it suitable for less stable signals, but it may introduce more noise and potential instability during transitions between chopping phases. Both approaches aim to prevent interference with the analog integrator by minimizing the use of chopping during integration, though the second method may require additional steps to manage instabilities during phase transitions.

Implementations of the present disclosure relate to an advanced analog-to-digital converter (ADC) circuit that integrates a digital offset ripple loop to enhance signal processing accuracy, particularly in systems that use chopping techniques to manage offset errors and noise. The core is a digital offset ripple loop that predicts and corrects offset during the signal conversion process, thereby improving the overall signal-to-noise ratio (SNR) and reducing low-frequency noise.

The proposed ADC circuit includes several key components: a modulation circuit that modulates the input signal to a higher frequency, a combination circuit that combines the modulated signal with a feedback signal, and a conversion circuit that digitizes the combined signal. The system also features a tracking register that stores and updates the digital signal, along with a prediction circuit that provides estimates of the digital signal based on historical data. This prediction helps in dynamically correcting the signal at critical moments, such as during chopping phase transitions. The feedback circuit converts the digital signal back to an analog feedback signal that is used to further refine the input signal, and the demodulation circuit restores the signal to its original frequency, ensuring the final digital output is accurate and noise-free.

One aspect of implementations of the present disclosure is the ability to handle offset errors and low-frequency noise through a combination of SAR and ΣΔ ADC techniques, along with a predictive digital loop. This approach allows the ADC to skip the SAR operation during phase transitions, reducing noise and enhancing accuracy, making it particularly useful for high-precision applications such as magnetic field sensing with Hall sensors.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F) PLAs), (field) programmable gate arrays ((F) PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### Aspects

The following provides an overview of some Aspects of the present disclosure:

Aspect 1: An analog-to-digital converter (ADC) circuit configured to process an input signal, the ADC circuit comprising: a modulation circuit configured to modulate the input signal at a modulation frequency to generate a modulated signal; a combination circuit configured to receive the modulated signal and combine it with a feedback signal to generate a combined signal; a conversion circuit configured to convert, at a sampling frequency, the combined signal into a digital signal; a tracking register configured to store and update the digital signal; a prediction circuit configured to estimate a future value of the digital signal based on historical data from the digital signal, and load the estimated future value into the tracking register at a modulation transition moment; a feedback circuit configured to convert a digital output signal of the tracking register into the feedback signal provided to the combination circuit; and a demodulation circuit configured to demodulate the digital signal at the modulation frequency to generate a digital demodulated output signal.

Aspect 2: The ADC circuit of Aspect 1, wherein the modulation circuit comprises an analog chopper circuit configured to modulate the input signal at a chopping frequency to generate an analog chopped signal as the modulated signal.

Aspect 3: The ADC circuit of any of Aspects 1-2, wherein the combination circuit is configured to determine a difference between the modulated signal and the feedback signal.

Aspect 4: The ADC circuit of any of Aspects 1-3, wherein the conversion circuit is configured to operate as Successive Approximation Register ADC during a first operational mode and as a Sigma-Delta ADC during a second operational mode.

Aspect 5: The ADC circuit of Aspect 4, wherein the first operational mode is an initial operational mode after initial startup of the ADC circuit and the second operational mode is a subsequent operational mode following the initial operational mode.

Aspect 6: The ADC circuit of any of Aspects 1-5, wherein the conversion circuit comprises: a signal processing circuit configured to process the combined signal and output a processed signal; a comparison circuit configured to compare the processed signal to a reference signal at the sampling frequency and generate a digital M-bit comparison output signal; and a conversion circuit configured to convert the digital M-bit comparison output signal into a digital N-bit signal.

Aspect 7: The ADC circuit of Aspect 6, wherein the signal processing circuit comprises an integrator and/or an amplifier.

Aspect 8: The ADC circuit of Aspect 7, wherein the signal processing circuit is configured as amplifier during a first operational mode and as integrator during a second operational mode.

Aspect 9: The ADC circuit of Aspect 6, wherein the comparison circuit comprises a comparator configured to generate, at each sampling moment, a 1-bit output signal based on the processed signal and the reference signal.

Aspect 10: The ADC circuit of any of Aspects 1-9, wherein the tracking register comprises an input configured to receive the estimated future value and update contents of the tracking register with the estimated future value at the modulation transition moment.

Aspect 11: The ADC circuit of any of Aspects 1-10, wherein the prediction circuit comprises: a Kalman filter configured to estimate the future value to be loaded into the tracking register by continuously updating an offset prediction based on a model of dynamics of the ADC circuit and current and previous digital N-bit signal samples.

Aspect 12: The ADC circuit of any of Aspects 1-11, wherein the prediction circuit comprises: a moving average filter configured to estimate the future value to be loaded into the tracking register by averaging a predefined number of recent digital N-bit signal samples.

Aspect 13: The ADC circuit of Aspect 6, wherein the prediction circuit comprises: a machine learning model trained to predict the future value to be loaded into the tracking register based on historical data and patterns identified in the digital N-bit signal.

Aspect 14: The ADC circuit of any of Aspects 1-13 further comprising: a sensor configured to generate an analog sensor signal as the input signal.

Aspect 15: The ADC circuit of Aspect 14, wherein the sensor comprises a spinning Hall sensor.

Aspect 16: The ADC circuit of any of Aspects 1-15, wherein the modulation frequency is lower than the sampling frequency.

Aspect 17: An analog-to-digital converter (ADC) circuit for converting an analog input signal to a digital output signal, the ADC circuit comprising: a forward path comprising: an analog chopper circuit configured to shift the analog input signal from an original frequency to a chopper frequency to generate a chopped analog signal; a conversion circuit configured to convert, at a sampling frequency, the chopped analog signal into a chopped digital signal; and a digital chopper circuit configured to shift the chopped digital signal from the chopper frequency to the original frequency; a feedback path including a digital-to-analog converter; and a digital offset compensation circuit configured to: predict an offset or signal value of the chopped digital signal based on previous sampling cycles; generate a digital compensation signal based on the predicted offset or signal value; and load the digital compensation signal into the feedback path at a start of a new chopping phase.

Aspect 18: The ADC circuit of Aspect 17, wherein the conversion circuit is configured to operate as an successive approximation register (SAR) ADC at a beginning of a chopping phase and as a sigma-delta (ZA) ADC during a remainder of the chopping phase, and wherein loading the digital compensation signal into the feedback path enables the conversion circuit to skip an SAR operation when changing from one chopping phase to another chopping phase.

Aspect 19: An analog-to-digital converter (ADC) method for processing an input signal, the method comprising: modulating the input signal at a modulation frequency to generate a modulated signal; combining the modulated signal with a feedback signal to generate a combined signal; converting, at a sampling frequency, the combined signal into a digital signal; storing and updating the digital signal in a tracking register; estimating a future value of the digital signal based on historical data from the digital signal, and loading the estimated future value into the tracking register at a modulation transition moment; converting a digital output signal of the tracking register into the feedback signal; and demodulating the digital signal at the modulation frequency to generate a digital demodulated output signal.

Aspect 20: A system configured to perform one or more operations recited in one or more of Aspects 1-19.

Aspect 21: An apparatus comprising means for performing one or more operations recited in one or more of Aspects 1-19.

Aspect 22: A non-transitory computer-readable medium storing a set of instructions, the set of instructions comprising one or more instructions that, when executed by a device, cause the device to perform one or more operations recited in one or more of Aspects 1-19.

Aspect 23: A computer program product comprising instructions or code for executing one or more operations recited in one or more of Aspects 1-19.

1. An analog-to-digital converter, ADC, circuit (200) configured to process an input signal, the ADC circuit (200) comprising:
a modulation circuit (210) configured to modulate the input signal at a modulation frequency to generate a modulated signal;
a combination circuit (206) configured to receive the modulated signal and combine it with a feedback signal (208) to generate a combined signal;
a conversion circuit (220) configured to convert, at a sampling frequency, the combined signal into a digital signal;
a tracking register (230) configured to store and update the digital signal;
a prediction circuit (240) configured to estimate a future value of the digital signal based on historical data from the digital signal, and load the estimated value into the tracking register (230) at a modulation transition moment;
a feedback circuit (250) configured to convert a digital output signal of the tracking register into the feedback signal provided to the combination circuit; and
a demodulation circuit (260) configured to demodulate the digital signal at the modulation frequency to generate a digital demodulated output signal.

2. The ADC circuit (200) of claim 1, wherein the modulation circuit (210) comprises an analog chopper circuit configured to modulate the input signal at a chopping frequency to generate an analog chopped signal as the modulated signal.

3. The ADC circuit (200) of any one of the previous claims, wherein the combination circuit (206) is configured to determine a difference between the modulated signal and the feedback signal.

4. The ADC circuit (200) of any one of the previous claims, wherein the conversion circuit (220) is configured to operate as Successive Approximation Register ADC during a first operational mode and as a Sigma-Delta ADC during a second operational mode.

5. The ADC circuit (200) of claim 4, wherein the first operational mode is an initial operational mode after initial startup of the ADC circuit (200) and the second operational mode is a subsequent operational mode following the initial operational mode.

6. The ADC circuit (200) of any one of the previous claims, wherein the conversion circuit (220) comprises:
a signal processing circuit (222) configured to process the combined signal and output a processed signal;
a comparison circuit (224) configured to compare the processed signal to a reference signal at the sampling frequency and generate a digital M-bit comparison output signal; and
a conversion circuit (226) configured to convert the digital M-bit comparison output signal into a digital N-bit signal.

7. The ADC circuit (200) of claim 6, wherein the signal processing circuit (222) comprises an integrator and/or an amplifier.

8. The ADC circuit (200) of claim 7, wherein the signal processing circuit (222) is configured as amplifier during a first operational mode and as integrator during a second operational mode.

9. The ADC circuit (200) of any one of claims 6 to 8, wherein the comparison circuit (224) comprises a comparator configured to generate, at each sampling moment, a 1-bit output signal based on the processed signal and the reference signal.

10. The ADC circuit (200) of any one of the previous claims, wherein the tracking register (230) comprises an input configured to receive the estimated value and update the tracking register's contents with the received estimated value at the modulation transition moment.

11. The ADC circuit (200) of any one of the previous claims, wherein the prediction circuit (240) comprises:
a Kalman filter configured to estimate the future value to be loaded into the tracking register by continuously updating an offset prediction based on a model of the ADC circuit's dynamics and current and previous digital N-bit signal samples.

12. The ADC circuit (200) of any one of the previous claims, wherein the prediction circuit (240) comprises:
a moving average filter configured to estimate the future value to be loaded into the tracking register by averaging a predefined number of recent digital N-bit signal samples.

13. The ADC circuit (200) of any one of the previous claims, wherein the prediction circuit (240) comprises:
a machine learning model trained to predict the future value to be loaded into the tracking register based on historical data and patterns identified in the digital N-bit signal.

14. The ADC circuit (200) of any one of the previous claims, further comprising:
a sensor (202) configured to generate an analog sensor signal as the input signal.

15. The ADC circuit (200) of claim 13, wherein the sensor (202) comprises a spinning Hall sensor.

16. The ADC circuit (200) of any one of the previous claims, wherein the modulation frequency is lower than the sampling frequency.

17. An ADC circuit (200) for converting an analog input signal to a digital output signal, the ADC circuit comprising:
a forward path comprising:
an analog chopper circuit (210) configured to shift the analog input signal from an original frequency to a chopper frequency to generate a chopped analog signal;
a conversion circuit (220) configured to convert, at a sampling frequency, the chopped analog signal into a chopped digital signal; and
a digital chopper circuit (260) configured to shift the chopped digital signal from the chopper frequency to the original frequency;
a feedback path including a digital-to-analog converter (250); and
a digital offset compensation circuit (230; 240) configured to:
predict an offset or signal value of the chopped digital signal based on previous sampling cycles;
generate a digital compensation signal based on the predicted offset or signal value; and
load the digital compensation signal into the feedback path at the start of a new chopping phase.

18. The ADC circuit (200) of claim 17, wherein the conversion circuit (220) is configured to operate as SAR ADC at the beginning of a chopping phase and as ΣΔ ADC during a remainder of the chopping phase, wherein loading the digital compensation signal into the feedback path enables the conversion circuit to skip the SAR operation when changing from one chopping phase to another.

19. An ADC method for processing an input signal, the method comprising:
modulating the input signal at a modulation frequency to generate a modulated signal;
combining the modulated signal with a feedback signal to generate a combined signal;
converting, at a sampling frequency, the combined signal into a digital signal;
storing and updating the digital signal in a tracking register;
estimating a future value of the digital signal based on historical data from the digital signal, and loading the estimated value into the tracking register at a modulation transition moment;
converting a digital output signal of the tracking register into the feedback signal; and
demodulating the digital signal at the modulation frequency to generate a digital demodulated output signal.
